(19) United States
(12) Patent Application Publication
(10) Pub. No.: US 2009/0243060 A1
(43) Pub. Date: Oct. 1, 2009

(54) Lead frame and package of semiconductor device

(75) Inventor: Hiroshi Saitoh, Iwata-shi (JP)

Correspondence Address: PILLSBURY WINTHROP SHAW PITTMAN LLP, P.O BOX 10500, McLean, VA, 22102, US

(73) Assignee: Yamaha Corporation, Hamamatsu-shi (JP)

(21) Appl. No.: 12/383,915

(22) Filed: Mar. 26, 2009

(30) Foreign Application Priority Data
Mar. 31, 2008 (JP) 2008-090474

(51) Int. Cl. H01L 23/495; H01L 23/48

(52) U.S. Cl. 257/676; 257/690; 257/E23.168; 257/E23.003

(57) ABSTRACT

A lead frame including a stage and a plurality of terminals is embedded in a mold resin including a base portion for mounting a semiconductor chip (e.g. a microphone chip), a peripheral wall disposed in the periphery of the base portion, and an extension portion extended outside of the peripheral wall, thus forming a package base. A plurality of holes is formed in the peripheral wall so as to expose the internal connection surface of the stage and the internal connection surfaces of the terminals. An extension portion of the stage is exposed on the extension portion of the mold resin in which the surfaces of the terminals are embedded. An extension portion (e.g. a brim) of a cover composed of a conductive material is attached to the extension portion of the mold resin of the package base, thus completely producing a semiconductor device.

### BACKGROUND OF THE INVENTION

1. Field of the Invention

The present invention relates to lead frames and packages for use in semiconductor devices. In particular, the present invention relates to lead frames partially embedded in mold resins in packages such as packages for microphones, sensors, SAW devices, quartz oscillators, and solid image pickup devices.

The present application claims priority on Japanese Patent Application No. 2008-90474, the content of which is incorporated herein by reference.

2. Description of the Related Art

Conventionally, semiconductor devices serving as silicon microphones and pressure sensors have been exemplarily designed such that microphone packages are held inside of hollow packages of a pre-mold type in which lead frames are molded with resins in advance.

Various semiconductor devices using pre-mold type packages have been developed and disclosed in various documents such as Patent Documents 1 and 2.
Patent Document 1: Japanese Unexamined Patent Application Publication No. 2007-66967
Patent Document 2: U.S. Pat. No. 6,781,231

Patent Document 1 teaches a semiconductor device in which a semiconductor chip is mounted on a stage located approximately at the center of a lead frame; a mold resin is integrally formed to cover the backside and the surrounding area of the stage; interconnection leads are extended externally from the stage so that the intermediate portions thereof are exposed on the upper surface of a peripheral wall of the mold resin extended out of the stage. A cup-shaped metal cover is put on the mold resin such that the peripheral end thereof joins the peripheral wall of the mold resin, thus forming a space surrounding the semiconductor chip. The metal cover is electrically connected to the exposed portions of the interconnection leads.

The distal ends of the interconnection leads and the distal ends of the leads which are disposed externally from the stage are exposed on the backside of the mold resin. They are connected to the circuitry of an external substrate (or an external circuit board) for mounting the semiconductor device thereon.

Patent Document 2 teaches a semiconductor device in which a semiconductor chip (e.g. a microphone chip) is mounted on the circuitry surface of a “flat” external substrate, which is then covered with and fixed to a metal case (or a metal cover).

The semiconductor device of Patent Document 1 is designed such that the exposed portions of the interconnection leads are connected to the stage of the lead frame and the metal cover so that the semiconductor chip is surrounded by metal, thus improving shield property. This semiconductor device can be manufactured with low cost because of a simple structure in which the lead frame is simply molded and unified with the resin. However, the manufacturing method needs a complex bending process in which the interconnection leads are vertically extended so that the intermediate portions thereof are exposed on the upper surface of the peripheral wall of the mold resin, then, the distal ends thereof are folded back and directed downwardly so that they are exposed on the backside of the mold resin.

In the semiconductor device of Patent Document 2 having the “flat” package, it is likely that a bonding agent used for fixing the semiconductor chip via die bonding may overflow so as to reach and cover the internal ends of leads. In order to prevent such a drawback in which the bonding agent overflows so as to reach the internal ends of leads, it is necessary to secure an adequate distance between the chip mounting area and the internal ends of leads, thus preventing the bonding agent from unexpectedly overflowing towards the internal ends of leads. This makes it difficult to reduce the overall size of the semiconductor device of Patent Document 2.

### SUMMARY OF THE INVENTION

It is an object of the present invention to provide a lead frame and a package each having a simple structure for reducing the overall size of a semiconductor device.

In the present invention, a lead frame, which is embedded in a box-shaped mold resin including a bottom portion, a peripheral wall disposed on the periphery of the base portion, and an extension portion extended from the periphery of the base portion outside of the peripheral wall, is constituted of a stage which is embedded in the base portion of the mold resin so that an extension portion thereof is extended in the extension portion of the mold resin, and a plurality of terminals which are formed in proximity to the stage and are distanced from each other in conjunction with the peripheral wall and the extension portion of the mold resin. A prescribed part of the surface of the stage serves as an internal connection surface in conjunction with the peripheral wall, while prescribed parts of the surfaces of the terminals serve as internal connection surfaces in conjunction with the peripheral wall. The other parts of the surfaces of the terminals serve as lower surfaces, which are lower than the surface of the stage in the thickness direction, in conjunction with the extension portion of the mold resin.

A package base is formed by sealing the lead frame with the mold resin in such a way that a plurality of holes is formed in the peripheral wall so as to partially expose the internal connection surface of the stage and the internal connection surfaces of the terminals, wherein the extension portion of the stage is exposed on the extension portion of the mold resin for embedding the surfaces of the terminals.

When a cover composed of a conductive material is attached to the extension portion of the mold resin for exposing the extension portion of the stage, it is possible to shield a semiconductor chip which is mounted on the stage and surrounded by the peripheral wall. In addition, holes are formed in the peripheral wall, which is disposed inwardly of the extension portion of the mold resin, so as to expose the internal connection surface of the stage and the internal connection surfaces of the terminals. In other words, the holes are encompassed within the peripheral wall while the extension portion of the mold resin is disposed outside of the peripheral wall. That is, when the semiconductor chip is fixed to the base portion of the package base via die bonding, it is possible to reliably prevent a bonding agent from overflowing towards the internal connection surfaces of the lead frame and the extension portion of the mold resin. This makes it possible to position the internal connection surfaces in proximity to the chip mounting area.

In addition, the cover is attached to the extension portion of the mold resin outside of the peripheral wall while the internal connection surfaces are exposed via the holes of the peripheral wall. This enables the lead frame to be entirely formed in a flat plate-shape.

It is possible to form an external connection surface projecting from the backside of the stage at a position vertically opposite to the internal connection surface of the stage, and a plurality of external connection surfaces projecting from the backsides of the terminals at positions vertically opposite to the internal connection surfaces of the terminals. In addition, it is possible to form a plurality of supports projecting from the backside of the stage with the same height as the external connection surfaces. The external connection surfaces and the supports are exposed on the backside of the mold resin. This makes it possible to stably hold the lead frame by an injection metal mold used for the formation of the mold resin such that the external connection surfaces and supports are brought into contact with the interior surface of the injection metal mold.

A package is constituted by the package base and the cover for covering the internal space surrounded by the peripheral wall, wherein the extension portion (e.g. brim) of the cover composed of a conductive material is electrically connected to the extension portion of the mold resin. Since the internal connection surfaces are exposed in only the holes of the peripheral wall which is disposed inwardly of the extension portion of the mold resin, it is possible to reliably prevent a bonding agent from overflowing toward the internal connection surfaces.

A semiconductor device is produced using the package in such a way that a semiconductor chip is mounted on the base portion of the mold resin of the package base just above the stage of the lead frame and is electrically connected to the internal connection surfaces of the stage and terminals via the holes of the peripheral wall.

A microphone package is produced using the package in such a way that a microphone chip is mounted on the package base just above the stage of the lead frame, wherein a sound hole communicating with the internal space is formed in either the cover or the package base. Since the internal space surrounded by the peripheral wall is reduced by disposing the peripheral wall close to the microphone chip, it is possible to increase the resonance frequency of the microphone package.

Furthermore, a plurality of small holes collectively serving as the sound hole can be formed in the exposed area of the stage which is exposed via a window hole formed in the mold resin.

As described above, it is possible to demonstrate the following effects.
(a) It is possible to prevent a bonding agent used for bonding the cover onto the extension portion of the mold resin of the package base from overflowing toward the internal connection surfaces which are exposed in only the holes of the peripheral wall.
(b) It is possible to dispose the internal connection surfaces close to the semiconductor chip because the internal connection surfaces are encompassed within the peripheral wall.
(c) It is possible to reduce the overall size of the semiconductor device, thus reducing the manufacturing cost of the semiconductor device.
(d) It is possible to achieve a high-density packaging due to a reduced area for mounting the semiconductor device on an external substrate.

### BRIEF DESCRIPTION OF THE DRAWINGS

These and other objects, aspects, and embodiments of the present invention will be described in more detail with reference to the following drawings.

FIG. 1 is a plan view showing the surface of a lead frame for use in a semiconductor device according to a first embodiment of the present invention.

FIG. 2 is a back view showing the backside of the lead frame shown in FIG. 1.

FIG. 3 is a perspective view showing a package base in which a mold resin is integrally formed with the lead frame.

FIG. 4 is a plan view of the package base shown in FIG. 3.

FIG. 5 is a back view of the package base shown in FIG. 3.

FIG. 6 is a longitudinal sectional view taken along line B-B in FIG. 4, which shows that a cover is applied to the package base for mounting semiconductor chips thereon.

FIG. 7 is a longitudinal sectional view taken along line C-C in FIG. 4, which shows that the cover is fixed to the package base.

FIG. 8 is a longitudinal sectional view showing the lead frame held by an injection metal mold.

FIG. 9 is a plan view showing the surface of a lead frame for use in a semiconductor device according to a second embodiment of the present invention.

FIG. 10 is a back view showing the backside of the lead frame shown in FIG. 9.

FIG. 11 is a perspective view showing a package base for use in the semiconductor device of the second embodiment.

FIG. 12 is a plan view of the package base shown in FIG. 11.

FIG. 13 is a back view of the package base shown in FIG. 11.

FIG. 14 is a longitudinal sectional view taken along line D-D in FIG. 12, which shows that a cover is fixed to the package base for mounting semiconductor chips.

FIG. 15 is a longitudinal sectional view showing the lead frame of FIG. 9 held by an injection metal mold.

FIG. 16 is a longitudinal sectional view showing a semiconductor device according to a third embodiment of the present invention.

FIG. 17 is an enlarged plan view showing a sound hole formed in a package base of the semiconductor device shown in FIG. 16.

FIG. 18 is a longitudinal sectional view showing a lead frame of the semiconductor device shown in FIG. 16 which is held by an injection metal mold.

### DESCRIPTION OF THE PREFERRED EMBODIMENTS

The present invention will be described in further detail by way of examples with reference to the accompanying drawings.

### 1. First Embodiment

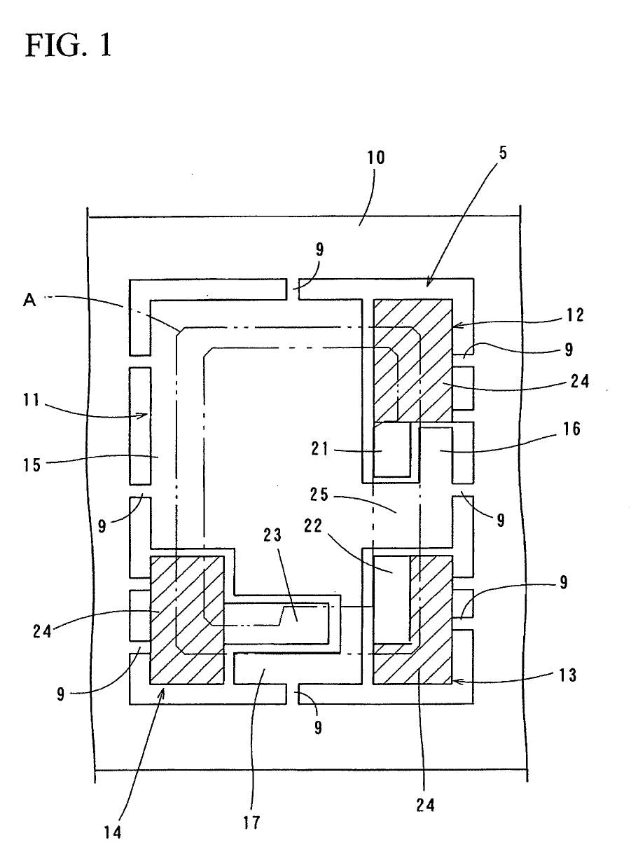

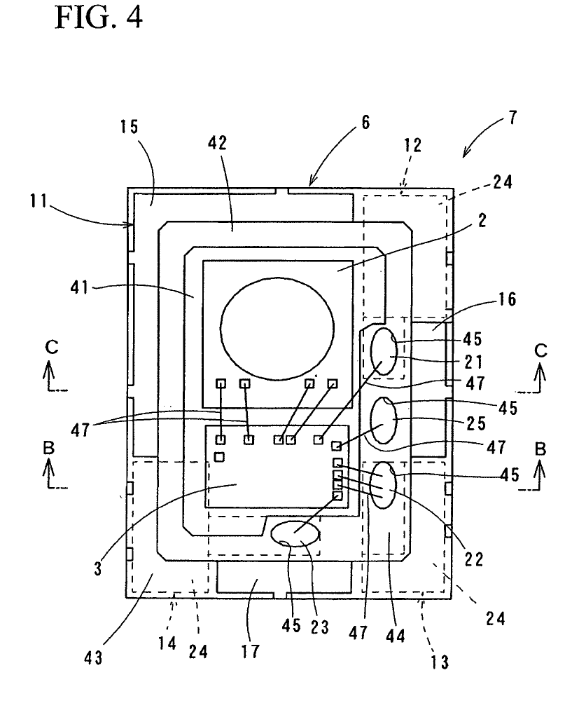

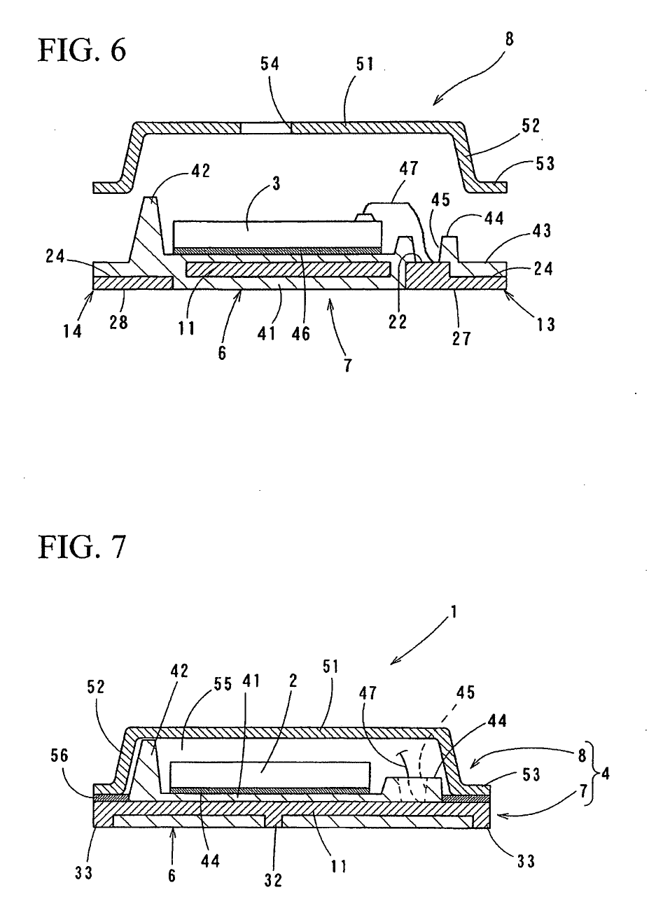

A semiconductor device 1 according to a first embodiment of the present invention will be described with reference to FIGS. 1 to 8. As shown in FIGS. 4, 6, and 7, the semiconductor device 1 stores a microphone chip 2 and a control chip (or a circuit chip) 3, which are encapsulated in a package 4. The package 4 is constituted of a package base 7 including a lead frame 5 having a flat plate-shape and a box-shaped mold resin 6 which is integrally formed with the lead frame 5, and a cover 8 for closing the upper portion of the package base 7.

A plurality of lead frames, each corresponding to the lead frame 5, is consecutively formed and linearly aligned in a band-shaped sheet of a metal plate subjected to press working. In this specification, an upper/lower direction is referred to as a vertical direction, and a left/right direction is referred to as a horizontal direction (or a lateral direction) with respect to the lead frame 5 shown in FIG. 1. Reference numeral 9 designates connections for connecting the lead frame 5 to an external frame 10 which is formed by way of punching.

The lead frame 5 includes a stage 11 in proximity to a power-supply terminal 12, an output terminal 13, and a gain terminal 14 which are disposed with prescribed distances therebetween and which are respectively connected to the external frame 10 via the connections 9.

The lead frame 5 is entirely formed in a rectangular shape, wherein the stage 11 is disposed around one corner defined by adjacent two sides which in turn circumscribe a main portion 15 thereof, and wherein two extension portions 16 and 17 are extended from and unified with the main portion 15. The distal ends of the extension portions 16 and 17 are disposed at approximately the center positions on the other adjacent two sides of the rectangular shape.

In addition, the three terminals 12 to 14 are respectively disposed at the other three corners of the rectangular shape surrounded by the external frame 10. Internal connection surfaces 21, 22, and 23 occupy the prescribed areas of the terminals 12, 13, and 14 in connection with the semiconductor chips 2 and 3, the details of which will be described later. Other areas of the terminals 12 to 14 (except for the internal connection surfaces 21 to 23) are reduced in thickness by way of half etching, thus forming lower surfaces 24 which are lower than the internal connection surfaces 21 to 23 in the thickness direction of the lead frame 5.

As shown in FIG. 1, the corner of the main portion 15 and the distal ends of the extension portions 16 and 17 are disposed in the periphery of the lead frame 5. In addition, the half-etched lower surfaces 24 are formed in the terminals 12 to 14 disposed at the other three corners in the periphery of the lead frame 5, wherein the internal connection surfaces 21 to 23 are disposed inwardly from the periphery of the lead frame 5. That is, the internal connection surfaces 21 to 23 of the terminals 12 to 14 are disposed inside an area A (circumscribed by dashed lines in FIG. 1) used for the formation of a peripheral wall of the mold resin 6 (which will be described later). A part of the extension portion 16 which is disposed inside the area A serves as a ground connection surface 25 for the stage 11. The corner of the main portion 15 of the stage 11, the distal ends of the extension portions 16 and 17, and the lower surfaces 24 of the terminals 12 to 14 are disposed in an extension area for use in the formation of an extension portion of the mold resin 6 outside of the area A for use in the formation of the peripheral wall of the mold resin 6.

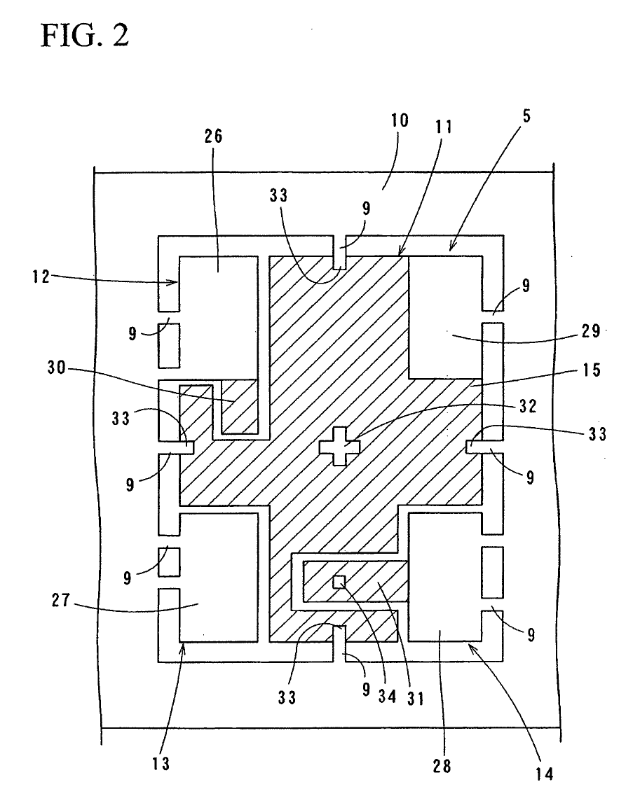

As shown in FIG. 2, the backside of the lead frame 5 is subjected to half etching (see hatching areas) except for the four rectangular corners thereof. The four rectangular corners of the backside of the lead frame 5 serve as external connection surfaces 26 to 29, which are placed in connection with an external substrate (or an external circuit board) for mounting the semiconductor chip 1 thereon.

In the backside of the stage 11 shown in FIG. 2, the external connection surface 29 is disposed at the upper-right corner of the main portion 15; the external connection surface 27 is disposed at the lower-left corner so as to match the overall rectangular backside of the terminal 13; the external connection surface 26 is disposed at the upper-left corner so as to match the backside of the terminal 12, from which an extension portion 30 is extended at the lower position; and the external connection surface 28 is disposed at the lower-right corner so as to match the backside of the terminal 14, from which an extension portion 31 is extended at the left-side position. Both the extension portions 30 and 31 are subjected to half etching and are thus reduced in thickness compared to the other area of the lead frame 5. All the external connection surfaces 26 to 28 of the terminals 12 to 14 as well as the external connection surface 29 of the stage 11 are formed in substantially the same rectangular shape having prescribed dimensions, wherein the four external connection surfaces 26 to 29 are disposed at the four corners of the backside of the lead frame 5. In this connection, the surfaces of the extension portions 30 and 31 of the terminals 12 and 14 correspond to the internal connection surfaces 21 and 23.

All the eight connections 9, which are disposed at four centers of four sides and in proximity to four corners, are formed at the same height as the external connection surface 29, thus forming supports 32 and 33 (which are brought into contact with a metal mold for use in the formation of the mold resin 6). Similar to the supports 32 and 33, a support 34 is formed at the same height as the external connection surface and is disposed at a prescribed position on the backside of the extension portion 31 of the terminal 14, i.e. at an approximately center position in the horizontal direction (or width direction) of the lead frame 5 in its lower section within the extension portion 31. All the connections 9 are not subjected to half etching so as to maintain the original thickness as the original metal plate.

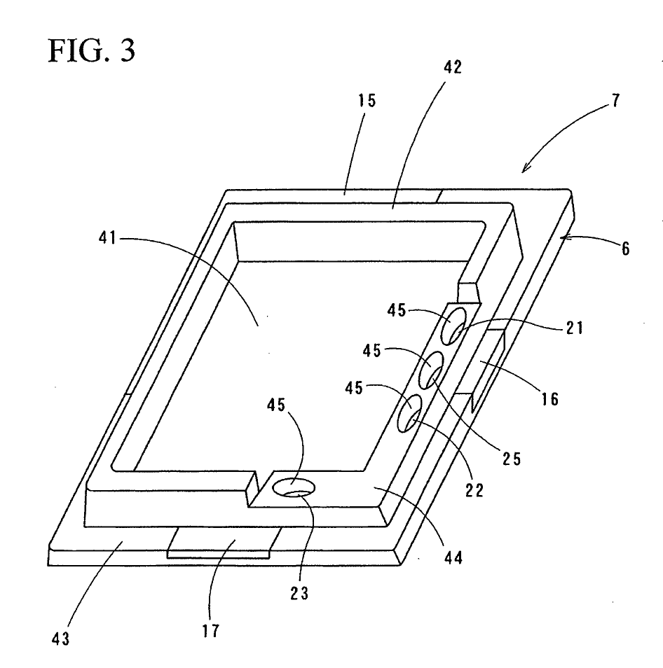

The mold resin 6 is formed integrally with the lead frame 5 having the above structure, thus forming the package base 7 shown in FIG. 3. As shown in FIGS. 3 and 4, the package base 7 is entirely formed in a box-shape and is constituted of a base portion 41 having a rectangular plate-shape which is elongated so as to mount the microphone chip 2 and the control chip 3 linearly adjoining together, a peripheral wall 42 having a prism-shape disposed on the periphery of the base portion 41, and an extension portion 43 which is integrally extended from the lower section of the peripheral wall 42.

Substantially the center portion of the lead frame 5, i.e. the surface and backside of the stage 11 occupying the inside of the area A shown in FIG. 1 (which is located inwardly of the peripheral wall 42), is entirely embedded in the base portion 41. The cross section of the peripheral wall 42 has a trapezoidal shape in which the width thereof gradually decreases from the lower section to the upper section thereof. In addition, the area A including a part of the main portion 15 of the stage 11, the intermediate portions of the extension portions 16 and 17 (in which the extension portion 16 serves as the internal connection surface 25), and the internal connection surfaces 21 to 23 and the lower surfaces 24 of the terminals 12 to 14 are partially embedded in the base portion 41. As shown in FIG. 3, a prescribed part of the peripheral wall 42 is lowered in height and slightly widened in width to form a wide portion 44. Four holes 45 for partially exposing the internal connection surface 25 of the stage 11 and the internal connection surfaces 21 to 23 of the terminals 12 to 14 are formed in the wide portion 44 of the peripheral wall 42.

The extension portion 43 which is extended externally from the peripheral wall 42 is formed in the same plane with the base portion 41 so as to arrange the external portion of the lead frame 5 externally of the area A shown in FIG. 1. The corners of the main portion 15 of the stage 11 and the distal ends of the extension portions 16 and 17 of the lead frame 5 are exposed on the surface of the extension portion 43, while the half-etched lower surfaces 24 of the terminals 12 to 14 are embedded in the extension portion 43 within the mold resin 6. The surface of the extension portion 43 lies in the same plane as the exposed surface of the stage 11 and the extension portions 16 and 17.

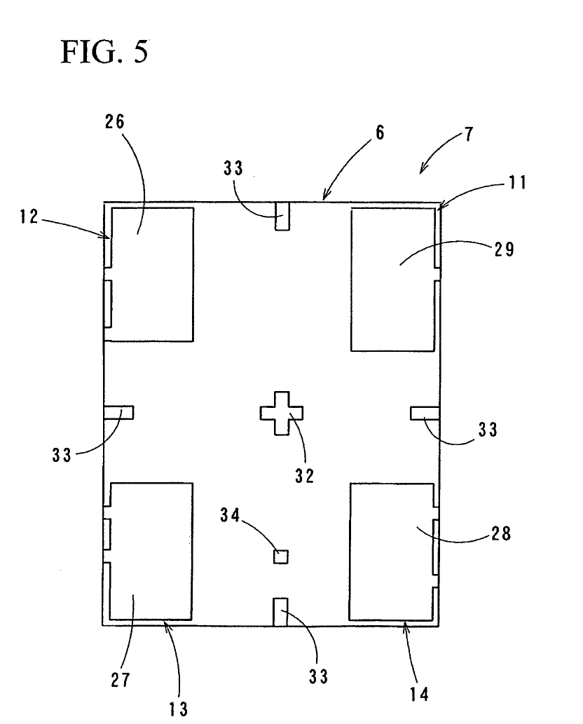

As shown in FIG. 5, the half-etched portions of the lead frame 5 are embedded in the backside of the mold resin 6, wherein the external connection surface 29 of the stage 11 and the external connection surfaces 26 to 28 of the terminals 12 to 14 are exposed on the four corners of the backside of the mold resin 6, and the supports 32, 33, and 34 disposed in the stage 11 are also exposed on the backside of the mold resin 6.

As shown in FIGS. 4, 6, and 7, the microphone chip 2 and the control chip 3 are fixed onto the base portion 41 of the package base 7 via die bonds 46, wherein they are electrically connected to the internal connection surfaces 21 to 23 of the terminals 12 to 14 and the internal connection surface 25 of the stage 11, which are exposed inside the holes 45 running through the wide portion 44 of the peripheral wall 42 of the mold resin 6, via bonding wires 47. The microphone chip 2 is designed such that a diaphragm electrode, which vibrates in response to pressure variations such as variations of sound pressure, is positioned opposite to a fixed electrode, thus detecting variations of electrostatic capacitance in response to vibration of the diaphragm electrode. The control chip 3 includes a power-supply circuit of the microphone chip 2 and an amplifier for amplifying the output signal of the microphone chip 2.

A cover 8 mounted on the package base 7 is composed of a conductive metal material such as copper and is subjected to drawing by the height of the peripheral wall 42 of the package base 7. A side wall 52 is formed in the periphery of a top portion 51 of the cover 8, wherein a brim 53 is formed at the lower end of the side wall 52 and is horizontally elongated in parallel with the top portion 51. A sound hole 54 is formed to run through a prescribed position of the top portion 51 of the cover 8. As shown in FIG. 7, when the cover 8 is mounted on the package base 7, the top portion 51 closes an internal space 55 circumscribed by the peripheral wall 42 of the package base 7, wherein the internal space 55 communicates with an external space via the sound hole 54, and wherein the side wall 52 is disposed outside of the peripheral wall 42 so that the brim 53 is mounted on the extension portion 43 of the package base 7. The package base 7 is assembled with the cover 8 in such a way that the brim 53 is fixed onto the extension portion 43 via a conductive adhesive 56, wherein the prescribed portions of the stage 11 exposed on the extension portion 43 are electrically connected to the cover 8 via the conductive adhesive 56. That is, the package base 7 is assembled with the cover 8, thus completely forming the package 4. In the package 4, the cover 8 is electrically connected to the stage 11 of the lead frame 5, and the semiconductor chips 2 and 3 are embraced within the internal space 55.

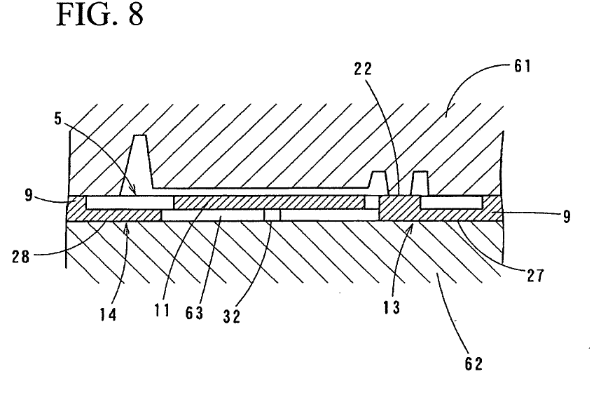

Next, a manufacturing method of the semiconductor device 1 will be described with reference to FIG. 8.

First, a metal plate is subjected to half etching while masking prescribed parts thereof so as to reduce the thickness of the hatching areas of the lead frame 5 shown in FIGS. 1 and 2 to approximately half of the original thickness. The overall outline is punched by press working, thus forming the lead frame 5 connected to the external frame 10 via the connections 9. The lead frame 5 may have small irregularities in half-etched portions but is substantially formed in a planar plate-shape.

Next, the lead frame 5 is placed in an injection metal mold, into which a melted resin is injected to produce the mold resin 6 embracing the lead frame 5 therein.

FIG. 8 shows that the lead frame 5 already subjected to press working is placed in the injection metal mold, wherein a cavity 63 for introducing the melted resin is formed between an upper mold 61 and a lower mold 62. In a plan view, the internal connection surfaces 21 to 23 of the terminals 12 to 14 and the internal connection surface 25 of the stage 11 are exposed on the surface of the lead frame 5. In a back view, the external connection surfaces 26 to 29, the supports 32 and 33 of the stage 11, and the support 34 of the terminal 14 are exposed in the backside of the lead frame 5. The exposed portions are formed in contact with the interior surfaces of the upper and lower molds 61 and 62 of the injection metal mold. The lead frame 5 is supported inside the cavity 63 such that the exposed portions formed on the surface and backside of the lead frame 5 come in contact with the interior surfaces of the upper and lower molds 61 and 62. In particular, the surface of the stage 11 is sealed with a resin in the base portion 41 of the package base 7, wherein a relatively large gap is formed between the surface 11 and the interior surface of the upper mold 61. The stage 11 is supported at both the surface and backside thereof because the supports 32 and 33 formed on the backside of the stage 11 come in contact with the interior surface of the lower mold 62 while the extension portion 43 of the package base 7 is tightly held between the upper mold 61 and the lower mold 62. That is, the lead frame 5 is firmly fixed in position by the upper and lower molds 61 and 62 so as not to deflect or move due to injection pressure.

After the mold resin 6 is integrally formed with the lead frame 5, the semiconductor chips 2 and 3 are fixed onto the base portion 41 of the package base 7 via the die bonds 46, and they are electrically connected to the internal connection surfaces 21 to 23 of the terminals 12 to 14 and the internal connection surface 25 of the stage 11, which are exposed in the holes 45 formed in the wide portion 44 of the peripheral wall 42, via wire bonding. Then, the cover 8, which is produced independently of the package base 7, is fixedly mounted on the package base 7 via the conductive adhesive 56 applied to the extension portion 43. In this state, a plurality of lead frames (each corresponding to the lead frame 5) is horizontally interconnected to adjoin together via the connections 9, while a plurality of covers (each corresponding to the cover 8) is correspondingly interconnected to adjoin together via connections (not shown), so that a plurality of package bases (each corresponding to the package base 7) is horizontally interconnected to adjoin together with prescribed pitches therebetween. Therefore, the covers are simultaneously bonded to the package bases having the lead frames.

After completion of the bonding process, the connections of the lead frames projecting from the mold resins and the connections of the covers are collectively subjected to cutting, thus producing individual pieces of products (each corresponding to the package 4 constituted of the lead frame 5, the package base 7, and the cover 8).

The semiconductor device 1 is mounted on an external substrate (or an external circuit board) in such a way that the terminals 12 to 14 and the external connection surfaces 26 to 29 of the stage 11 are soldered to the external substrate. In the semiconductor device shown in FIG. 7, the stage 11 embedded in the base portion 41 is disposed below the semiconductor chips 2 and 3; the semiconductor chips 2 and 3 are connected to the internal connection surface 25 of the stage 21; the cover is fixedly bonded to the extension portions 16 and 17 of the stage 11 via the conductive adhesive 56; and the cover 8 covers above the semiconductor chips 2 and 3. The semiconductor chips 2 and 3 are surrounded by the stage 11 and the cover 8, and the external connection surface 29 of the stage 11 is grounded via the external substrate; hence, it is possible to shield the semiconductor chips 2 and 3 from external electromagnetic waves.

In the package base 7, the peripheral wall 42 is vertically disposed between the base portion 41 for fixedly mounting the semiconductor chips 2 and 3 and the extension portion 43 which is fixed with the brim 53 of the cover 8, and the internal connection surfaces 21 to 23 of the terminals 12 to 14 and the internal connection surface 25 of the stage 11 are exposed in the holes 45 formed in the wide portion 44 of the peripheral wall 42; hence, the peripheral wall 42 dams up the die bond 46 and the conductive adhesive 56, which are thus prevented from overflowing towards the holes 45 via the peripheral wall 42. This allows the chip mounting area of the base portion 41 to be positioned close to the internal connection surfaces 21 to 23 and 25; thus, it is possible to reduce the overall area of the semiconductor device 1.

In addition, the internal connection surfaces 21 to 23 of the terminals 12 to 14 and the internal connection surface 25 of the stage 11 are exposed inside the holes 45 formed in the wide portion 44 of the peripheral wall 42; the cover is fixed to the package base 7 in such a way that the brim 53 is fixed to the extension portion 43 which lies in the same plane as the base portion 41 outside of the peripheral wall 42; and the lead frame 5 is entirely formed in a flat plate-shape. Thus, it is possible to reduce the overall size of the lead frame compared to conventionally-known lead frames which are partially bent so as to form terminals and connections for covers.

Therefore, it is possible to reduce the necessary area for mounting the semiconductor chip I on an external substrate, whereby the semiconductor device I can be packaged at a high density without causing interference with the circuitry of the external substrate.

### 2. Second Embodiment

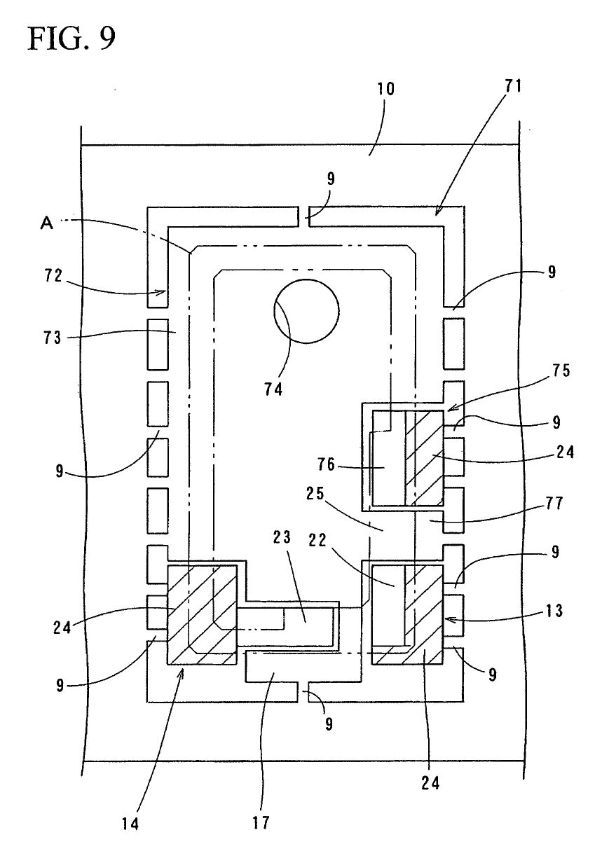

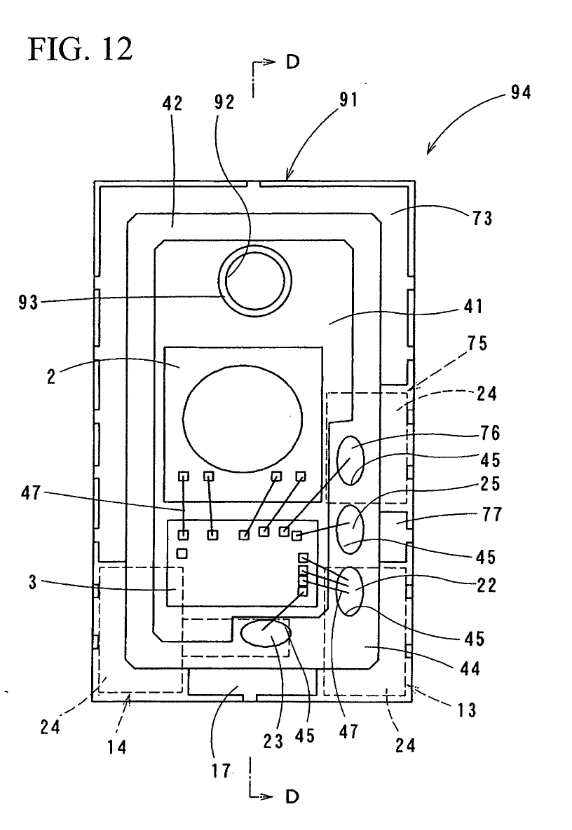

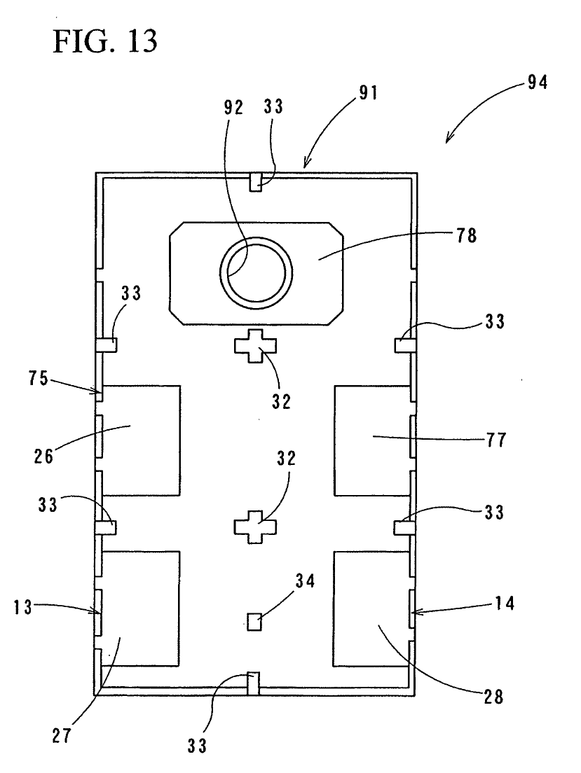

Next, a semiconductor device 97 according to a second embodiment of the present invention will be described with reference to FIGS. 9 to 15, in which parts identical to those shown in FIG. 1 to 8 are designated by the same reference numerals; hence, duplicate descriptions thereof will not be repeated below.

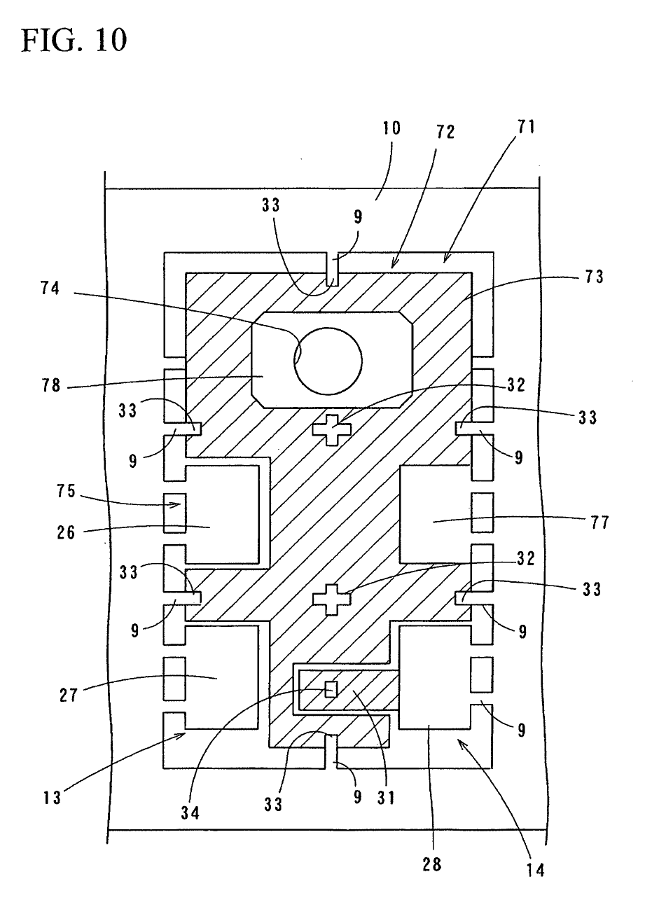

Compared to the semiconductor device 1 of the first embodiment in which the sound hole 54 is formed in the cover 8, the semiconductor device 97 of the second embodiment is designed such that a sound hole is formed in a package base 94. FIGS. 9 and 10 show a lead frame 71 in which a main portion 73 of a stage 72 is vertically elongated to be longer than the main portion 15 of the stage 11 of the lead frame 5 used in the first embodiment, wherein a lower hole 74 serving as a sound hole is formed in the main portion 73 of the stage 72.

Similar to the lead frame 5 of the first embodiment, the terminals 13 and 14 are disposed at two corners of the lead frame 71 of the second embodiment, which is not equipped with the terminal 12. The lead frame 71 is equipped with an additional terminal 75 which is disposed at approximately the center position in the vertical direction. Similar to the terminal 13 having no extension portion, the terminal 75 is formed in a rectangular shape, a part of which serves as an internal connection surface 76. Similar to the stage 11 of the first embodiment, the stage 72 has the extension portion 17, while it has another extension portion 77 which is straightened in shape in proximity to the terminal 75.

The backside of the stage 72 is largely subjected to half-etching (see hatching areas shown in FIG. 10). An external connection surface 77 is formed at the center position in the vertical direction along the side of the stage 72 opposite to the side along which the terminal 75 is disposed at the center position. A support 78 is formed to surround the backside area of the lower hole 74. Since the main portion 73 of the stage 72 is vertically elongated, two supports 32 are each formed at the center position in the width direction, and two pairs of supports 33 are formed together with the connections on the opposite sides of the stage 72.

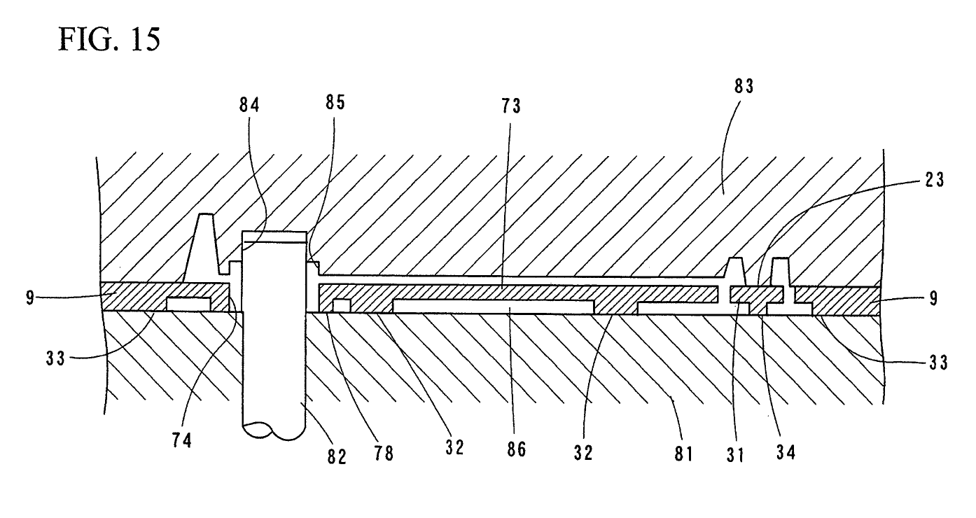

The lead frame 71 is subjected to press working, then, it is placed in an injection metal mold as shown in FIG. 15. In the injection metal mold, a pin 82 whose diameter is slightly smaller than the diameter of the lower hole 74 of the lead frame 71 partially projects above a lower mold 81, while a hole 84 for inserting the distal end of the pin 82 and a counterbore 85 whose diameter is slightly larger than the diameter of the hole 84 are concentrically formed in an upper mold 83 in conformity with the pin 82 of the lower mold 81. When the molds 81 and 83 are clamped so as to insert the pin 82 into the hole 84, a cavity 86 is formed therebetween in such a way that a cylindrical space is formed around the pin 82 due to the counterbore 85.

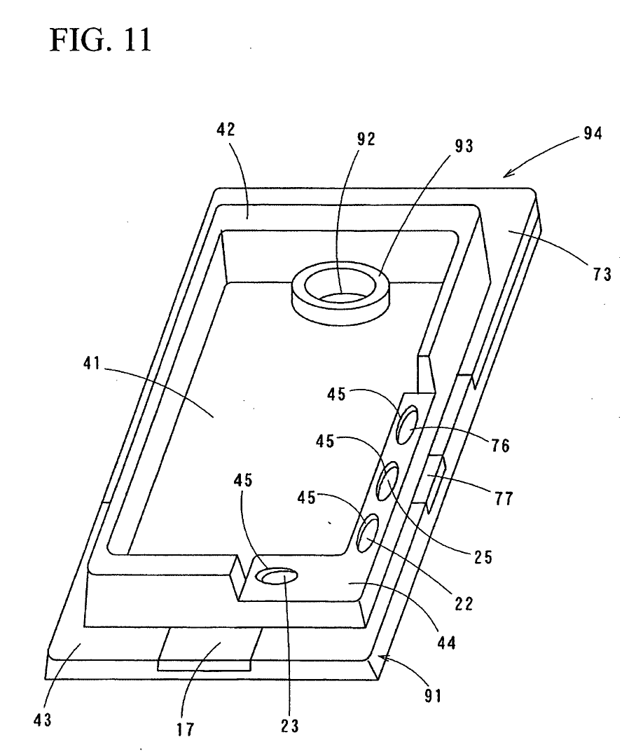

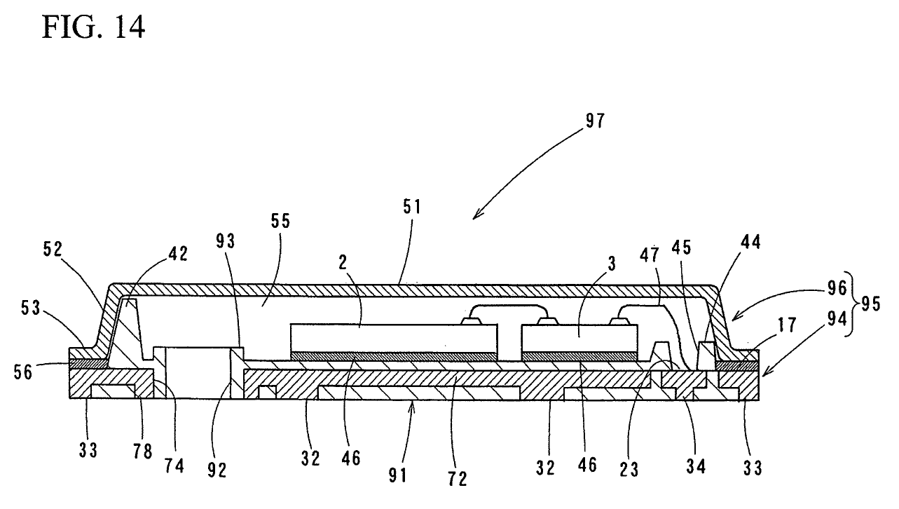

When a melted resin is injected into the injection metal mold tightly holding the lead frame 71, a mold resin 91 is integrally formed with the lead frame 71 so as to form the package base 94 as shown in FIGS. 11 to 14 in such a way that a sound hole 92 is formed by the pin 82 in the base portion 41 thereof, and a cylindrical wall 93 is formed to surround the sound hole 92 on the base portion 41. The cylindrical wall 93 dams up the die bond 46 used for bonding the semiconductor chips 2 and 3 on the base portion 41 so as to prevent it from overflowing into the sound hole 92. Correspondingly, a cover 96 having no hole (see FIG. 14) is attached to the package base 94, thus completely producing the semiconductor device 97. Similar to the cover 8 of the first embodiment, the cover 96 of the second embodiment is composed of a conductive metal material. Since the cover 96 is electrically connected to the lead frame 71, the internal space formed between the package base 94 and the cover 96 is electromagnetically shield in the semiconductor device 97.

### 3. Third Embodiment

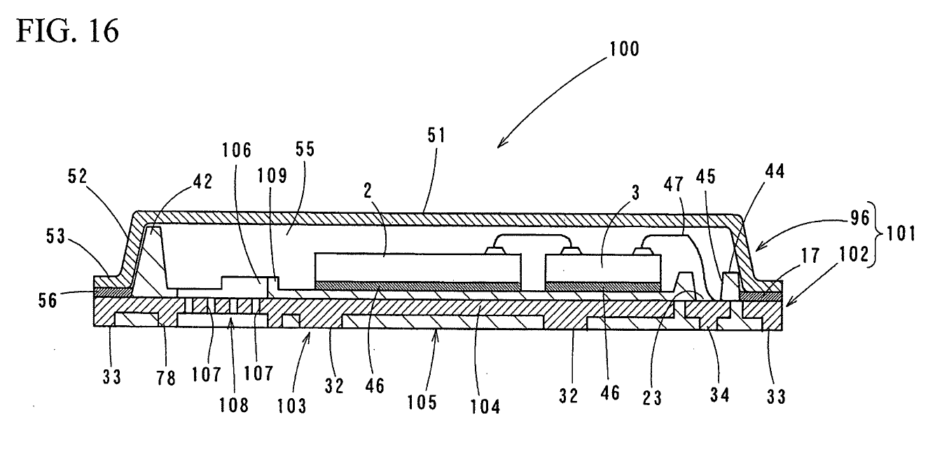

A semiconductor device 100 according to a third embodiment of the present invention is designed based on the semiconductor device 97 of the second embodiment in which the sound hole 92 is formed in the package base 94 and is described with reference to FIGS. 16 to 18.

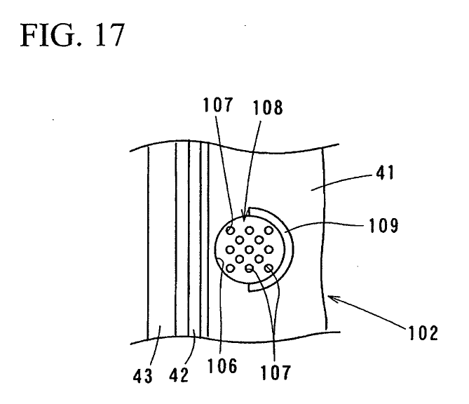

The semiconductor device 100 of the third embodiment is composed of a package 101 constituted of the cover 96 and a package base 102 in which a lead frame 103 having a stage 104 is sealed with a mold resin 105. As shown in FIGS. 16 and 17, a circular area of the mold resin 105 is extracted so as to form a window hole 106, in which a circular area of the stage 104 is correspondingly exposed. A plurality of small holes 107 is formed to run through the exposed circular area of the stage 104, thus forming a sound hole 108. An arc-shaped wall 109 is disposed between the sound hole 108 and the semiconductor chip 2 mounted on the base portion 41 of the package base 102.

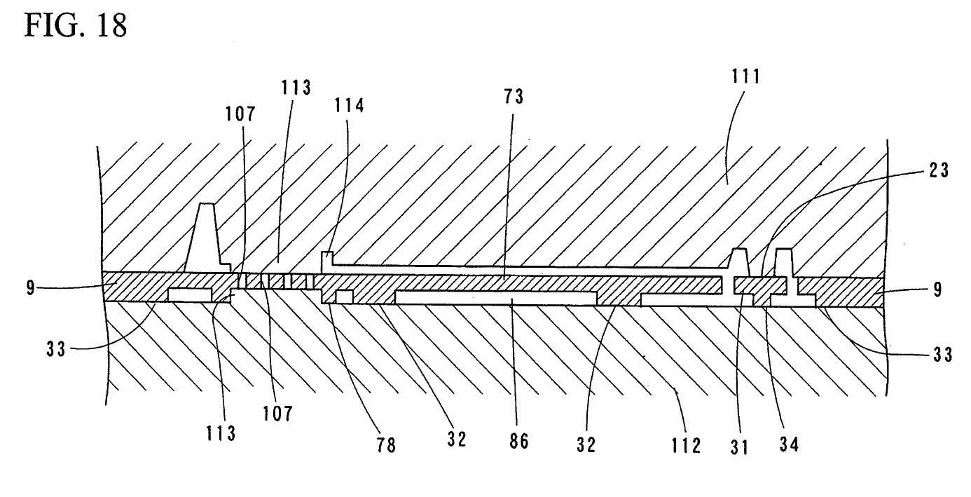

In the manufacturing of the package base 102, the small holes 107 of the sound hole 108 are simultaneously formed by way of half-etching on the lead frame 103. Similar to the lead frames 5 and 71 of the first and second embodiments, the lead frame 103 of the third embodiment is subjected to half-etching, which is performed using a mask having small holes in conformity with the sound hole 108, thus forming the small holes 107. In the injection molding of the mold resin 105 as shown in FIG. 18, the lead frame 103 is held between an upper mold 111 and a lower mold 112 with circular projections 113 with respect to the sound hole 108, thus closing the small holes 107. An arc-shaped channel 114 is formed in the upper mold 111 in proximity to the circular projection 113. As shown in FIGS. 16 and 17, a circular area of the stage 104 is exposed so as to form the sound hole 108 having the small holes 107 therein, while the arc-shaped wall 109 is formed to circumscribe approximately half the area of the sound hole 108. The arc-shaped wall 109 can be reshaped into a cylindrical shape as similar to the cylindrical wall 93 formed in the package base 71 of the second embodiment.

The above structure allows the sound hole 108 to be efficiently formed by way of etching, which forms a part of the manufacturing method. Since small holes 107 are used to form the sound hole 108 and are each reduced in size, it is possible to reliably prevent foreign matter such as dust from entering into the internal space 55 of the package 101, and it is possible to reduce noise as well.

The present invention is not necessarily limited to the above embodiments, which can be modified in various ways.

The above embodiments are directed to semiconductor devices adapted to microphone packages; but this is not a restriction. The present invention can be applied to other types of sensors (other than microphones) such as quartz oscillators, high-frequency SWA filters, duplexers, solid image pickup devices, and MEMS devices (such as acceleration sensors, angular velocity sensors, magnetic sensors, pressure sensors, infrared sensors, micro-mirror arrays, silicon microphones, silicon oscillators, and RF-MEMS switches) as well as flow sensors, and wind pressure sensors. Microphones need through holes such as sound holes allowing the internal space to communicate with the external space, whereas some sensors do not need through holes, while flow sensors need two through holes.

In case of airtight-sealed and vacuum-sealed devices, for example, after an airtight-sealed devices such as a quartz oscillator is fixed to the package base 7, the cover 8 is bonded to the package base 7 in a vacuum sealing apparatus (not shown). It is possible to secure a sufficiently large contact area between the cover 8 and the package base 7 having the peripheral wall 42 and the extension portion 43. Only the internal connection surfaces 21 to 23 (corresponding to the surfaces of the terminals 12 to 14) and the internal connection surface 25 of the stage 11 are exposed inside the package 4 while the other areas of the package base 7 are sealed with the mold resin 4; hence, it is possible to seal the internal space formed by the package base 7 and the cover 8 in an airtight manner. Thus, the semiconductor package according to the present invention can be preferably applied to airtight-sealed and vacuum-sealed devices, whose internal spaces are sealed in an airtight manner and in a vacuum stage, such as quartz oscillators and SAW filters.

The above embodiments are each designed such that four external connection surfaces corresponding to the stage and terminals are formed for the purposes of power supply, output, gain control, and ground respectively, whereas the semiconductor device of the present invention needs at least three external connection surfaces for the purposes of power supply, output, and ground respectively, wherein it is possible to form two external connection surfaces for the purpose of ground. The number of terminals depends upon the number of semiconductor chips and the types of semiconductor chips, wherein the number of semiconductor chips installed in the semiconductor device is not necessarily limited to two. It is possible to increase the number of terminals connected to the external frame 10 by means of the connections 9, thus achieving five-terminal or six-terminal configuration, for example.

The above embodiments are each designed such that the lead frame is entirely retained in a flat shape while forming prescribed height differences (such as lower surfaces) by way of half-etching; but this is not a restriction. It is possible to form height differences (or irregularities) by way of embossing or coining, for example.

It is possible to form recesses which are formed to engage with external connection surfaces for use in the formation of the mold resin by the injection metal mold, thus forming the external connection surfaces and supports that project from the backside of the mold resin. In this case, the backside of the mold resin is floated above the surface of an external substrate. The above embodiments are each designed such that the cover is bonded to the package base via the conductive adhesive which is applied to the extension portion of the package base in advance; but this is not a restriction. It is possible to fix the cover to the package base via an adhesive sheet which is attached to the extension portion of the package base.

Lastly, the present invention is not necessarily limited to the above embodiments and variations, which can be further modified within the scope of the invention as defined by the appended claims.

What is claimed is:

1. A lead frame, which is embedded in a box-shaped mold resin including a bottom portion, a peripheral wall disposed on a periphery of the base portion, and an extension portion extended from the periphery of the base portion outside of the peripheral wall, comprising:
a stage embedded in the base portion of the mold resin, wherein an extension portion of the stage is extended in the extension portion of the mold resin; and
a plurality of terminals which are formed in proximity to the stage and are distanced from each other in conjunction with the peripheral wall and the extension portion of the mold resin,
wherein a prescribed part of a surface of the stage serves as an internal connection surface in conjunction with the peripheral wall, while prescribed parts of surfaces of the terminals serve as internal connection surfaces in conjunction with the peripheral wall, and
wherein other parts of the surfaces of the terminals serve as lower surfaces, which are lower than the surface of the stage in a thickness direction, in conjunction with the extension portion of the mold resin.

2. The lead frame according to claim 1, wherein the extension portion of the stage is extended in conjunction with the extension portion of the mold resin.

3. The lead frame according to claim 1, wherein an external connection surface is formed to project from a backside of the stage at a position vertically opposite to the internal connection surface of the stage, and a plurality of external connection surfaces is formed to project from a plurality of backsides of the terminals at positions vertically opposite to the internal connection surfaces of the terminals.

4. The lead frame according to claim 3 further comprising a plurality of supports which project from the backside of the stage with a same height as the external connection surfaces.

5. A package base comprising:
a lead frame including a stage and a plurality of terminals; and
a mold resin including a bottom portion, a peripheral wall disposed on a periphery of the base portion, and an extension portion extended from the periphery of the base portion outside of the peripheral wall,
wherein the stage is embedded in the base portion of the mold resin, an extension portion of the stage is extended and exposed on the extension portion of the mold resin, and a plurality of terminals is formed in proximity to the stage and is distanced from each other in conjunction with the peripheral wall and the extension portion of the mold resin,
wherein a prescribed part of a surface of the stage serves as an internal connection surface in conjunction with the peripheral wall, while prescribed parts of surfaces of the terminals serve as internal connection surfaces in conjunction with the peripheral wall,
wherein other parts of the surfaces of the terminals serve as lower surfaces, which are lower than the surface of the stage in a thickness direction, in conjunction with the extension portion of the mold resin, and
wherein a plurality of holes is formed in the peripheral wall of the mold resin so as to expose the internal connection surface of the stage and the internal connection surfaces of the terminals.

6. The package base according to claim 5, wherein an external connection surface is formed to project from a backside of the stage at a position vertically opposite to the internal connection surface of the stage, and a plurality of external connection surfaces is formed to project from a plurality of backsides of the terminals at positions vertically opposite to the internal connection surfaces of the terminals, and wherein the external connection surface of the stage and the external connection surfaces of the terminals are exposed on a backside of the mold resin.

7. The package base according to claim 6 further comprising a plurality of supports which project from the backside of the stage with a same height as the external connection surfaces, so that the supports and the external connection surfaces are exposed on a backside of the mold resin.

8. A package comprising:
a package base constituted of a lead frame including a stage and a plurality of terminals, and a mold resin including a bottom portion, a peripheral wall disposed on a periphery of the base portion, and an extension portion extended from the periphery of the base portion outside of the peripheral wall; and
a cover composed of a conductive material, which is assembled with the package base so as to cover an internal space surrounded by the peripheral wall in such a way that a peripheral portion thereof is electrically connected to the extension portion of the mold resin of the package base,
wherein the stage is embedded in the base portion of the mold resin, an extension portion of the stage is extended and exposed on the extension portion of the mold resin, and a plurality of terminals is formed in proximity to the stage and is distanced from each other in conjunction with the peripheral wall and the extension portion of the mold resin,
wherein a prescribed part of a surface of the stage serves as an internal connection surface in conjunction with the peripheral wall, while prescribed parts of surfaces of the terminals serve as internal connection surfaces in conjunction with the peripheral wall,
wherein other parts of the surfaces of the terminals serve as lower surfaces, which are lower than the surface of the stage in a thickness direction, in conjunction with the extension portion of the mold resin, and
wherein a plurality of holes is formed in the peripheral wall of the mold resin so as to expose the internal connection surface of the stage and the internal connection surfaces of the terminals.

9. The package according to claim 8, wherein an external connection surface is formed to project from a backside of the stage at a position vertically opposite to the internal connection surface of the stage, and a plurality of external connection surfaces is formed to project from a plurality of backsides of the terminals at positions vertically opposite to the internal connection surfaces of the terminals, and wherein the external connection surface of the stage and the external connection surfaces of the terminals are exposed on a backside of the mold resin.

10. The package according to claim 9 further comprising a plurality of supports which project from the backside of the stage with a same height as the external connection surfaces, so that the supports and the external connection surfaces are exposed on a backside of the mold resin.

11. A semiconductor device comprising:
a semiconductor chip;
a package base constituted of a lead frame including a stage and a plurality of terminals, and a mold resin including a bottom portion, a peripheral wall disposed on a periphery of the base portion, and an extension portion extended from the periphery of the base portion outside of the peripheral wall; and
a cover composed of a conductive material, which is assembled with the package base so as to cover an internal space surrounded by the peripheral wall in such a way that a peripheral portion thereof is electrically connected to the extension portion of the mold resin of the package base,
wherein the stage is embedded in the base portion of the mold resin, an extension portion of the stage is extended and exposed on the extension portion of the mold resin, and a plurality of terminals is formed in proximity to the stage and is distanced from each other in conjunction with the peripheral wall and the extension portion of the mold resin,
wherein a prescribed part of a surface of the stage serves as an internal connection surface in conjunction with the peripheral wall, while prescribed parts of surfaces of the terminals serve as internal connection surfaces in conjunction with the peripheral wall,
wherein other parts of the surfaces of the terminals serve as lower surfaces, which are lower than the surface of the stage in a thickness direction, in conjunction with the extension portion of the mold resin, and
wherein a plurality of holes is formed in the peripheral wall of the mold resin so as to expose the internal connection surface of the stage and the internal connection surfaces of the terminals, so that the semiconductor chip is mounted on the stage and is electrically connected to the internal connection surface of the stage and the internal connection surfaces of the terminals via the holes of the peripheral wall.

12. The semiconductor device according to claim 11, wherein an external connection surface is formed to project from a backside of the stage at a position vertically opposite to the internal connection surface of the stage, and a plurality of external connection surfaces is formed to project from a plurality of backsides of the terminals at positions vertically opposite to the internal connection surfaces of the terminals, and wherein the external connection surface of the stage and the external connection surfaces of the terminals are exposed on a backside of the mold resin.

13. The semiconductor device according to claim 12 further comprising a plurality of supports which project from the backside of the stage with a same height as the external connection surfaces, so that the supports and the external connection surfaces are exposed on a backside of the mold resin.

14. A microphone package comprising:
a microphone chip;
a package base constituted of a lead frame including a stage and a plurality of terminals, and a mold resin including a bottom portion, a peripheral wall disposed on a periphery of the base portion, and an extension portion extended from the periphery of the base portion outside of the peripheral wall; and
a cover composed of a conductive material, which is assembled with the package base so as to cover an internal space surrounded by the peripheral wall in such a way that a peripheral portion thereof is electrically connected to the extension portion of the mold resin of the package base,
wherein the stage is embedded in the base portion of the mold resin, an extension portion of the stage is extended and exposed on the extension portion of the mold resin, and a plurality of terminals is formed in proximity to the stage and is distanced from each other in conjunction with the peripheral wall and the extension portion of the mold resin,
wherein a prescribed part of a surface of the stage serves as an internal connection surface in conjunction with the peripheral wall, while prescribed parts of surfaces of the terminals serve as internal connection surfaces in conjunction with the peripheral wall,
wherein other parts of the surfaces of the terminals serve as lower surfaces, which are lower than the surface of the stage in a thickness direction, in conjunction with the extension portion of the mold resin,
wherein a plurality of holes is formed in the peripheral wall of the mold resin so as to expose the internal connection surface of the stage and the internal connection surfaces of the terminals, so that the semiconductor chip is mounted on the stage and is electrically connected to the internal connection surface of the stage and the internal connection surfaces of the terminals via the holes of the peripheral wall, and
wherein a sound hole communicating with internal space is formed in either the cover or the package base.

15. The microphone package according to claim 14, wherein an external connection surface is formed to project from a backside of the stage at a position vertically opposite to the internal connection surface of the stage, and a plurality of external connection surfaces is formed to project from a plurality of backsides of the terminals at positions vertically opposite to the internal connection surfaces of the terminals, and wherein the external connection surface of the stage and the external connection surfaces of the terminals are exposed on a backside of the mold resin.

16. The microphone package according to claim 15 further comprising a plurality of supports which project from the backside of the stage with a same height as the external connection surfaces, so that the supports and the external connection surfaces are exposed on a backside of the mold resin.

17. The microphone package according to claim 14, wherein a plurality of small holes collectively serving as the sound hole is formed in an exposed area of the stage which is exposed via a window hole formed in the mold resin.
